(19) United States
(12) Patent Application Publication
(10) Pub. No.: US 2026/0280510 A1
(43) Pub. Date: Sep. 17, 2026

(54) ELECTRONIC COMPONENT

(71) Applicant: TDK Corporation, Tokyo (JP)

(72) Inventors: Yuta ASHIDA, Tokyo (JP); Shuhei SAWAGUCHI, Tokyo (JP); Ryosuke KOMATSU, Tokyo (JP); Kyohei SAITO, Tokyo (JP); Tatsuya KOYAMA, Tokyo (JP); Misako KUDO, Tokyo (JP); Hiroki UESUGI, Tokyo (JP)

(73) Assignee: TDK Corporation, Tokyo (JP)

(21) Appl. No.: 19/562,984

(22) Filed: Mar. 11, 2026

(30) Foreign Application Priority Data
Mar. 14, 2025 (JP) 2025-041687

(51) Int. Cl. H03H 5/00; H03H 1/00

(52) U.S. Cl. CPC H03H 5/003; H03H 1/00; H03H 2001/0085

(57) ABSTRACT

An electronic component includes: an element body having a pair of end surfaces facing each other in a first direction, a pair of main surfaces facing each other in a second direction, and a pair of side surfaces facing each other in a third direction; and a first resonator, a second resonator, and a third resonator disposed in the element body, in which the first resonator has a first conductor extending in the second direction, the first conductor extends in a direction in which the first resonator, the second resonator, and the third resonator are arranged side by side as viewed from the second direction, and the first resonator is disposed between the second resonator and the third resonator.

### TECHNICAL FIELD

The present disclosure relates to an electronic component.

### BACKGROUND

WO 2020/026889 A discloses an electronic component including: a resonator including a via electrode portion formed in a dielectric substrate, and a first strip line connected to one end of the via electrode portion and facing a first shielding conductor among a plurality of shielding conductors formed so as to surround the via electrode portion; an input/output terminal coupled to a second shielding conductor among the plurality of shielding conductors; and a first capacitor electrode pattern coupled to the input/output terminal, the first capacitor electrode pattern being capacitively coupled to a second capacitor electrode pattern connected to the via electrode portion, or being capacitively coupled to the first strip line.

### SUMMARY

An electronic component according to one aspect of the present disclosure includes: an element body having a pair of end surfaces facing each other in a first direction, a pair of main surfaces facing each other in a second direction, and a pair of side surfaces facing each other in a third direction; and a first resonator, a second resonator, and a third resonator disposed in the element body, in which the first resonator includes a first conductor extending in the second direction, the first conductor extends in a direction in which the first resonator, the second resonator, and the third resonator are arranged side by side as viewed from the second direction, and the first resonator is disposed between the second resonator and the third resonator.

### BRIEF DESCRIPTION OF THE DRAWINGS

FIG. 1 is a perspective view of an electronic component according to a first embodiment;

FIG. 2 is a transparent perspective view of the electronic component illustrated in FIG. 1;

FIG. 3 is a view of the electronic component illustrated in FIG. 2 as viewed from a side of one side surface;

FIG. 4 is a view of the electronic component illustrated in FIG. 2 as viewed from a side of the other side surface;

FIG. 5 is a view of the electronic component illustrated in FIG. 2 as viewed from a side of one end surface;

FIG. 6 is a view of the electronic component illustrated in FIG. 2 as viewed from a side of the other end surface;

FIG. 7 is a view of the electronic component illustrated in FIG. 2 as viewed from a side of one main surface;

FIG. 8 is a view illustrating conductors included in the electronic component;

FIG. 9 is a view illustrating a cross-sectional configuration of a conductor;

FIG. 10 is a transparent perspective view of an electronic component according to a second embodiment;

FIG. 11 is a view of the electronic component illustrated in FIG. 10 as viewed from a side of one side surface;

FIG. 12 is a view of the electronic component illustrated in FIG. 10 as viewed from a side of the other side surface;

FIG. 13 is a view of the electronic component illustrated in FIG. 10 as viewed from a side of one end surface;

FIG. 14 is a view of the electronic component illustrated in FIG. 10 as viewed from a side of the other end surface;

FIG. 15 is a view of the electronic component illustrated in FIG. 10 as viewed from a side of one main surface; and

FIG. 16 is a view illustrating a cross-sectional configuration of a conductor.

### DETAILED DESCRIPTION

### Problems to be Solved by the Present Disclosure

In a resonator of the above-described electronic component, a conductor (via electrode portion) connected to a shielding conductor has a single columnar shape (rod shape). In this configuration, an eddy current is generated in the conductor in a concentrated manner by a magnetic flux generated when a current flows, and a loss (eddy current loss) caused by the eddy current is generated, so that a Q factor may be lowered. Furthermore, in an electronic component including a plurality of resonators, it has been difficult to adjust electromagnetic coupling between the resonators (inductors of the resonators).

An object of one aspect of the present disclosure is to provide an electronic component capable of facilitating adjustment of electromagnetic coupling while improving a Q factor.

### Effects of Present Disclosure

According to one aspect of the present disclosure, the adjustment of the electromagnetic coupling can be facilitated while improving the Q factor.

### DESCRIPTION OF EMBODIMENTS OF PRESENT DISCLOSURE

First, contents of embodiments of the present disclosure will be listed and described. At least some of the embodiments described below may be combined in any manner.

(1) An electronic component according to one aspect of the present disclosure includes: an element body having a pair of end surfaces facing each other in a first direction, a pair of main surfaces facing each other in a second direction, and a pair of side surfaces facing each other in a third direction; and a first resonator, a second resonator, and a third resonator disposed in the element body, in which the first resonator includes a first conductor extending in the second direction, the first conductor extends in a direction in which the first resonator, the second resonator, and the third resonator are arranged side by side as viewed from the second direction, and the first resonator is disposed between the second resonator and the third resonator.

In the electronic component according to one aspect of the present disclosure, the first conductor extends in the direction in which the first resonator, the second resonator, and the third resonator are arranged side by side as viewed from the second direction. As a result, in the electronic component, since a cross-sectional area of the first conductor can be increased, a resistance value of the first conductor can be reduced, and a Q factor can be improved.

In the electronic component according to one aspect of the present disclosure, the first conductor extends in the direction in which the first resonator, the second resonator, and the third resonator are arranged side by side as viewed from the second direction as described above. In this configuration, in the electronic component, the first resonator is disposed between the second resonator and the third resonator. As a result, in the electronic component, electromagnetic coupling between the first resonator and the second resonator and electromagnetic coupling between the first resonator and the third resonator can be adjusted by adjusting a position of the first resonator with respect to each of the second resonator and the third resonator. As described above, in the electronic component, the electromagnetic coupling can be adjusted by the position of the first resonator provided between the second resonator and the third resonator. Therefore, in the electronic component, the adjustment of the electromagnetic coupling can be simplified.

(2) The electronic component of (1) above may include a pair of side electrodes disposed on the pair of side surfaces, respectively, and connected to the ground.

(3) In the electronic component of (2) above, the first conductor may be disposed in a central region of the element body in the third direction as viewed from the second direction. In this configuration, since a distance between the first conductor and each of the pair of side electrodes can be secured, a space formed between the first conductor and each of the pair of side electrodes can be secured. Thus, in the electronic component, a region where a magnetic flux is generated can be secured, and a magnetic field can be formed around the first conductor. Therefore, in the electronic component, since the generation of the eddy current can be suppressed, the generation of the loss caused by the eddy current can be suppressed, and the Q factor can be improved.

(4) The electronic component of (2) or (3) above may include a ground conductor electrically connected to the pair of side electrodes, and a capacitor conductor, in which one end of the first conductor may be connected to the ground conductor, and the other end of the first conductor may be connected to the capacitor conductor. In this configuration, a magnetic field can be formed around the first conductor. Therefore, in the electronic component, since the generation of the eddy current can be suppressed, the generation of the loss caused by the eddy current can be suppressed, and the Q factor can be improved.

(5) In the electronic component of any one of (1) to (4) above, the second resonator may include a second conductor extending in the second direction, the third resonator may include a third conductor extending in the second direction, and at least one of the second conductor and the third conductor may have a length in the first direction longer than a length in the third direction as viewed from the second direction. In this configuration, since a cross-sectional area of at least one of the second conductor and the third conductor can be increased, a resistance value of at least one of the second conductor and the third conductor can be reduced, and the Q factor can be improved.

(6) In the electronic component of any one of (1) to (5) above, each of the first conductor, the second conductor, and the third conductor may have a length in the first direction longer than a length in the third direction as viewed from the second direction. In this configuration, since cross-sectional areas of the first conductor, the second conductor, and the third conductor can be increased, resistance values of the first conductor, the second conductor, and the third conductor can be reduced, and the Q factor can be improved.

(7) In the electronic component of any one of (1) to (6) above, the first resonator may include a plurality of the first conductors.

(8) The electronic component of any one of (1) to (7) above may further include a fourth resonator disposed in the element body, in which the fourth resonator may include a fourth conductor extending in the second direction, and the third resonator, the first resonator, the second resonator, and the fourth resonator may be disposed in order from a side of one of the pair of end surfaces to a side of the other of the pair of end surfaces in the first direction.

(9) In the electronic component of (8) above, the fourth conductor may have a length in the first direction longer than a length in the third direction as viewed from the second direction.

(10) The electronic component of (8) or (9) above may include: a first terminal electrode disposed on the one end surface; and a second terminal electrode disposed on the other end surface, in which the third resonator may be electrically connected to the first terminal electrode, and the fourth resonator may be electrically connected to the second terminal electrode.

(11) In the electronic component of (5) above, the second resonator may include a plurality of the second conductors.

(12) In the electronic component of (7) above, the plurality of first conductors may be arranged side by side in the third direction.

(13) In the electronic component of any one of (1) to (12) above, the cross-sectional shape of the first conductor orthogonal to the second direction may be a shape in which a plurality of circles overlap.

(14) In the electronic component of any one of (1) to (13) above, the first conductor may have a recess on a side surface, the recess extending in the second direction.

(15) The electronic component of (2) above may include a plurality of conductors disposed in both end portions of the element body in the first direction and in both end portions of the element body in the third direction, the plurality of conductors extending in the second direction.

(16) In the electronic component of (15) above, the plurality of conductors may be electrically connected to the pair of side electrodes.

(17) The electronic component of (2) above may include: a first ground conductor disposed closer to one of the pair of main surfaces; and a second ground conductor disposed closer to the other of the pair of main surfaces, in which one end of the first conductor may be connected to the first ground conductor, the other end of the first conductor may be connected to a capacitor conductor, and the capacitor conductor may face the second ground conductor in the second direction.

(18) The electronic component of (17) above may include: a first capacitor conductor that is the capacitor conductor included in the first resonator; a second capacitor conductor that is a capacitor conductor included in the second resonator; and a conductor disposed between each of the first capacitor conductor and the second capacitor conductor, and the second ground conductor in the second direction.

(19) The first conductor, the second conductor above, and the third conductor may be disposed on the same straight line in the first direction.

(20) In the electronic component of (10) above, the first terminal electrode and the second terminal electrode may be formed to wrap both of the pair of main surfaces from the pair of end surfaces, respectively.

### Details of Embodiments of Present Disclosure

Specific examples of embodiments of the present disclosure will be described below with reference to the drawings. The present disclosure is not limited to these examples, but is indicated by the claims, and is intended to include all modifications within the meaning and scope equivalent to the claims. In the description of the drawings, the same elements are denoted by the same reference numerals, and redundant description thereof will be omitted.

### First Embodiment

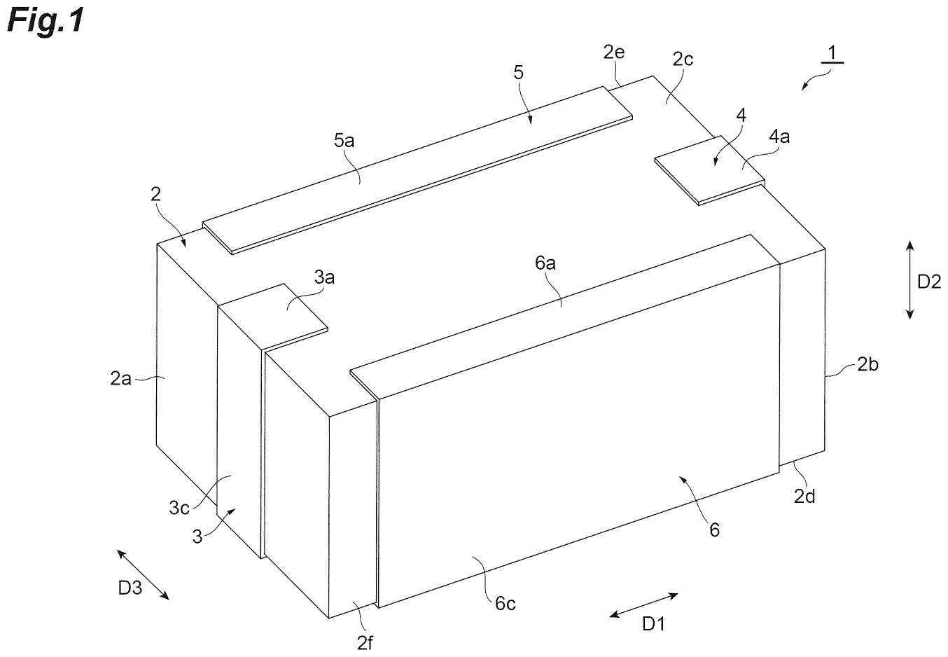

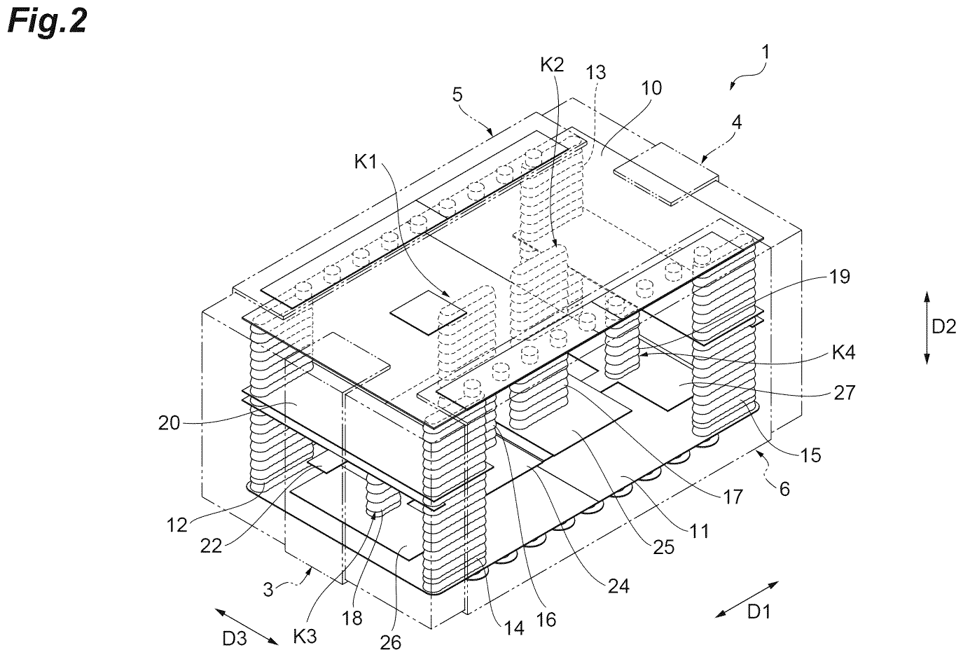

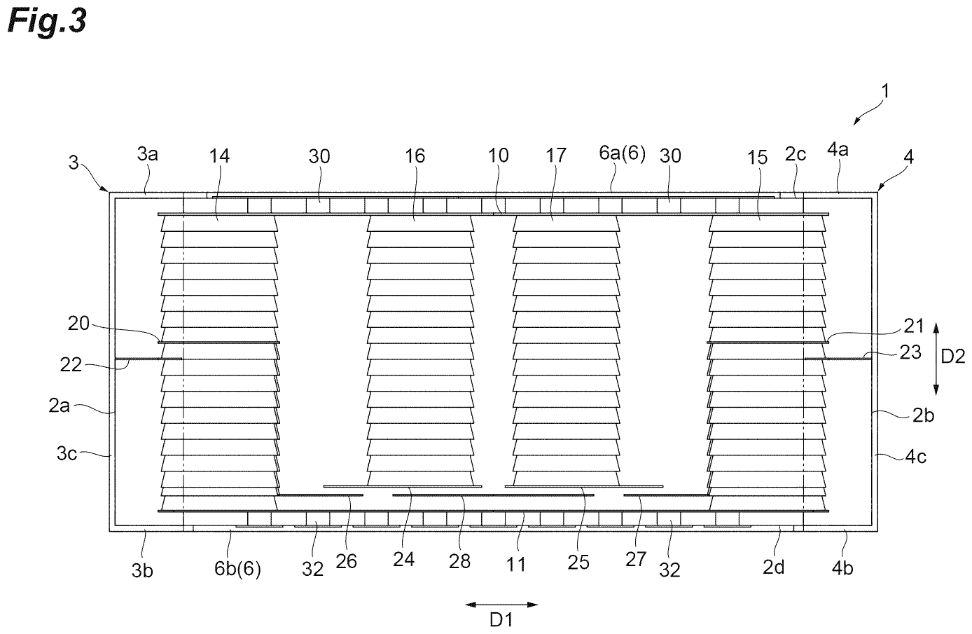

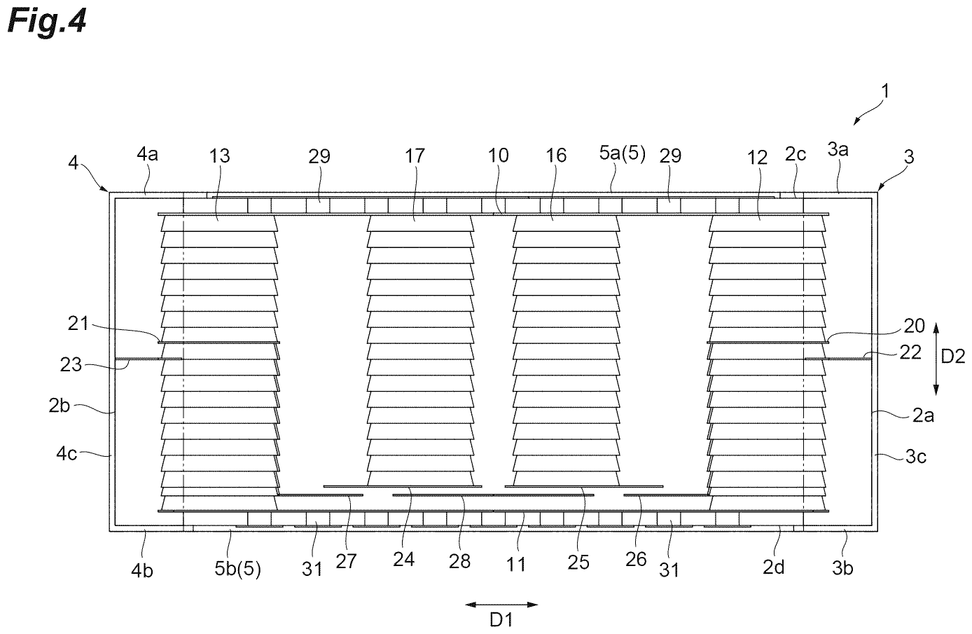

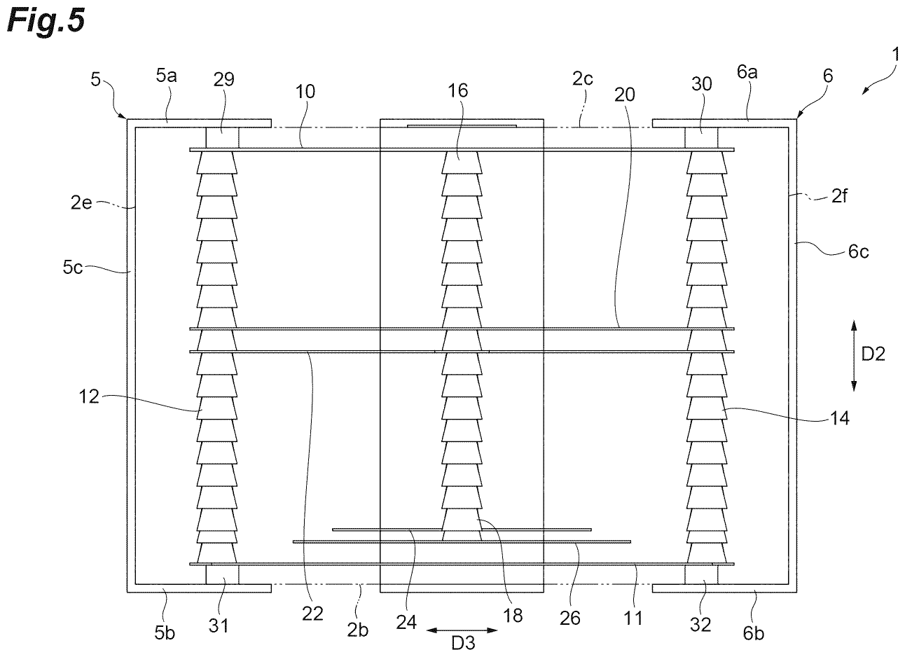

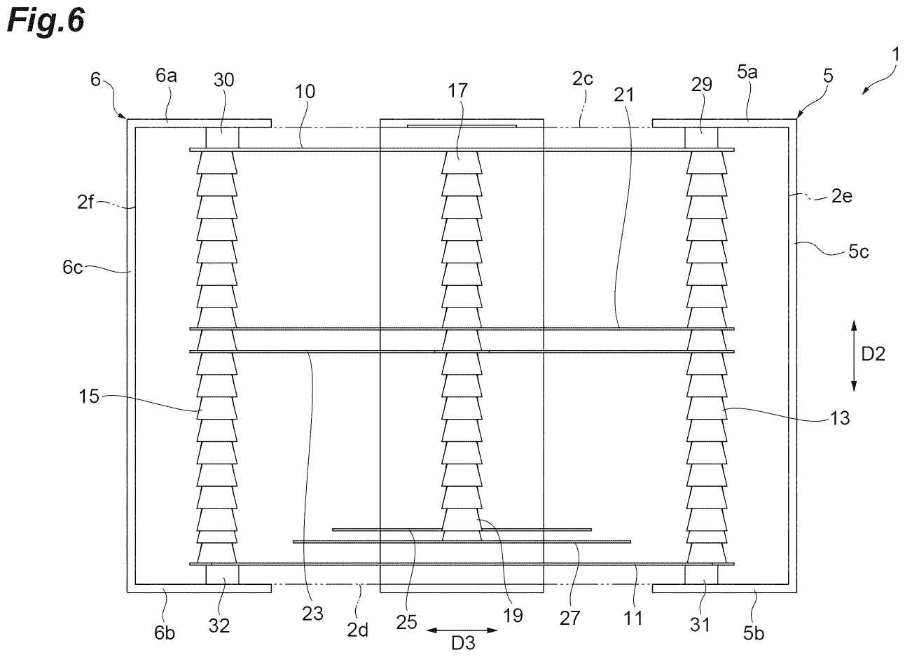

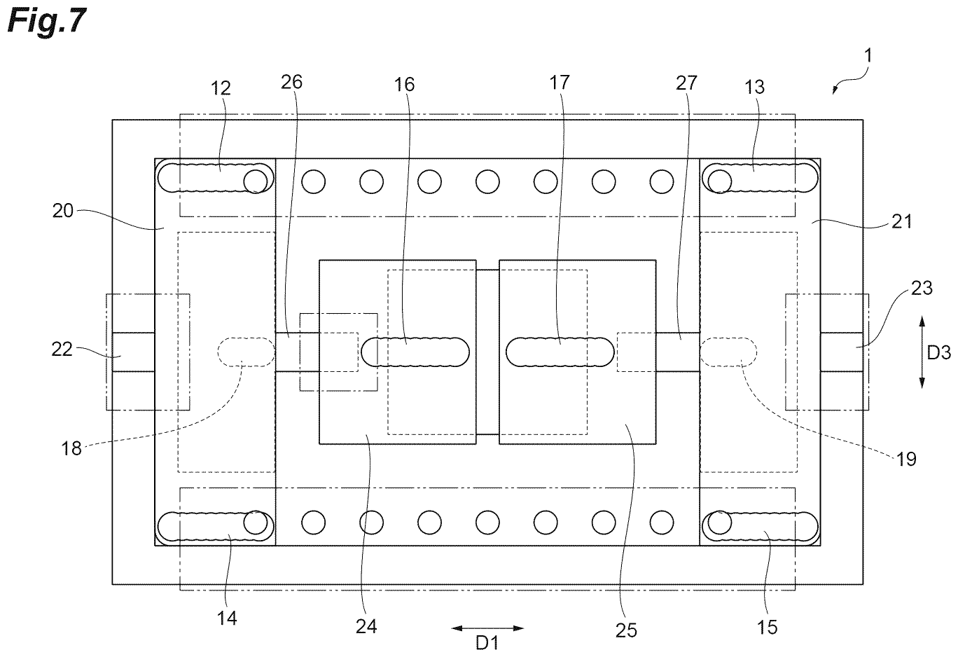

FIG. 1 is a perspective view of an electronic component according to a first embodiment. FIG. 2 is a transparent perspective view of the electronic component illustrated in FIG. 1. FIG. 3 is a view of the electronic component illustrated in FIG. 2 as viewed from a side of one side surface. FIG. 4 is a view of the electronic component illustrated in FIG. 2 as viewed from a side of the other side surface. FIG. 5 is a view of the electronic component illustrated in FIG. 2 as viewed from a side of one end surface. FIG. 6 is a view of the electronic component illustrated in FIG. 2 as viewed from a side of the other end surface. FIG. 7 is a view of the electronic component illustrated in FIG. 2 as viewed from a side of one main surface. As illustrated in FIGS. 1 to 6, an electronic component 1 includes an element body 2, a first terminal electrode 3, a second terminal electrode 4, a third terminal electrode (side electrode) 5, and a fourth terminal electrode (side electrode) 6, which are respectively disposed on the element body 2, a first resonator K1, a second resonator K2, a third resonator K3, and a fourth resonator K4.

The element body 2 has a rectangular parallelepiped shape. The rectangular parallelepiped shape includes a rectangular parallelepiped shape in which corner portions and ridge line portions are chamfered, and a rectangular parallelepiped shape in which corner portions and ridge line portions are rounded. The element body 2 has, as the outer surfaces thereof, a pair of end surfaces 2a and 2b facing each other, a pair of main surfaces 2c and 2d facing each other, and a pair of side surfaces 2e and 2f facing each other. A facing direction in which the pair of end surfaces 2a and 2b face each other is a first direction D1. A facing direction in which the pair of main surfaces 2c and 2d face each other is a second direction D2. A facing direction in which the pair of side surfaces 2e and 2f face each other is a third direction D3.

In the present embodiment, the length of the element body 2 in the first direction D1 is longer than the length of the element body 2 in the third direction D3. That is, the first direction D1 is a longitudinal direction of the element body 2. The second direction D2 is a height direction of the element body 2, and is orthogonal to the first direction D1. The third direction D3 is a width direction of the element body 2, and is orthogonal to the second direction D2 and the first direction D1.

The pair of end surfaces 2a and 2b extend in the second direction D2 to connect the pair of main surfaces 2c and 2d. The pair of end surfaces 2a and 2b also extend in the third direction D3 (short side direction of the pair of main surfaces 2c and 2d). The pair of side surfaces 2e and 2f extend in the second direction D2 to connect the pair of main surfaces 2c and 2d. The pair of side surfaces 2e and 2f also extend in the first direction D1 (long side direction of the pair of main surfaces 2c and 2d). When the electronic component 1 is mounted on other electronic device (for example, a circuit board, an electronic component, or the like), the main surface 2d can be defined as a mounting surface facing the other electronic device.

The element body 2 is configured by stacking a plurality of dielectric layers (not illustrated). Each dielectric layer is stacked in the second direction D2. That is, the second direction D2 is a stacking direction. The element body 2 has the plurality of stacked dielectric layers. Each dielectric layer is, for example, a sintered body of a ceramic green sheet containing, for example, a dielectric material (dielectric ceramic such as BaTiO₃-based, Ba(Ti, Zr)O₃-based, or (Ba, Ca)TiO₃-based). In the actual element body 2, the plurality of dielectric layers are integrated to such an extent that boundaries between the layers cannot be visually recognized.

The first terminal electrode 3 is disposed on a side of the end surface 2a of the element body 2. The first terminal electrode 3 is disposed at the center of the end surface 2a in the third direction D3. The first terminal electrode 3 is formed so as to cover a part of the end surface 2a along the second direction D2 of the element body 2, and is formed on a part of the main surface 2c and a part of the main surface 2d. The first terminal electrode 3 includes a first portion 3a, a second portion 3b, and a third portion 3c. The first portion 3a, the second portion 3b, and the third portion 3c are integrally formed. The first portion 3a is disposed on the main surface 2c. The second portion 3b is disposed on the main surface 2d. The third portion 3c is disposed on the end surface 2a. The third portion 3c extends along the second direction D2 and electrically connects the first portion 3a and the second portion 3b.

The second terminal electrode 4 is disposed on a side of the end surface 2b of the element body 2. The second terminal electrode 4 is disposed at the center of the end surface 2b in the third direction D3. The second terminal electrode 4 is formed so as to cover a part of the end surface 2b along the second direction D2 of the element body 2, and is formed on a part of the main surface 2c and a part of the main surface 2d. The second terminal electrode 4 includes a first portion 4a, a second portion 4b, and a third portion 4c. The first portion 4a, the second portion 4b, and the third portion 4c are integrally formed. The first portion 4a is disposed on the main surface 2c. The second portion 4b is disposed on the main surface 2d. The third portion 4c is disposed on the end surface 2b. The third portion 4c extends along the second direction D2 and electrically connects the first portion 4a and the second portion 4b.

The third terminal electrode 5 is disposed on a side of the side surface 2e of the element body 2. The third terminal electrode 5 is formed so as to cover a part of the side surface 2e along the second direction D2 of the element body 2, and is formed on a part of the main surface 2c and a part of the main surface 2d. The third terminal electrode 5 includes a first portion 5a, a second portion 5b, and a third portion 5c. The first portion 5a, the second portion 5b, and the third portion 5c are integrally formed. The first portion 5a is disposed on the main surface 2c. The first portion 5a extends along the first direction D1. The second portion 5b is disposed on the main surface 2d. The second portion 5b extends along the first direction D1. The third portion 5c is disposed on the side surface 2e. The third portion 5c extends along the second direction D2 and electrically connects the first portion 5a and the second portion 5b. The third portion 5c extends along the first direction D1.

The fourth terminal electrode 6 is disposed on a side of the side surface 2f of the element body 2. The fourth terminal electrode 6 is formed so as to cover a part of the side surface 2f along the second direction D2 of the element body 2, and is formed on a part of the main surface 2c and a part of the main surface 2d. The fourth terminal electrode 6 includes a first portion 6a, a second portion 6b, and a third portion 6c. The first portion 6a, the second portion 6b, and the third portion 6c are integrally formed. The first portion 6a is disposed on the main surface 2c. The first portion 6a extends along the first direction D1. The second portion 6b is disposed on the main surface 2d. The second portion 6b extends along the first direction D1. The third portion 6c is disposed on the side surface 2f. The third portion 6c extends along the second direction D2 and electrically connects the first portion 6a and the second portion 6b. The third portion 6c extends along the first direction D1.

The first terminal electrode 3, the second terminal electrode 4, the third terminal electrode 5, and the fourth terminal electrode 6 contain a conductive material (for example, Ag or Pd or the like). The first terminal electrode 3, the second terminal electrode 4, the third terminal electrode 5, and the fourth terminal electrode 6 are configured as a sintered body of a conductive paste containing a conductive material (for example, Ag powder or Pd powder or the like). A plating layer may be formed on the surfaces of the first terminal electrode 3, the second terminal electrode 4, the third terminal electrode 5, and the fourth terminal electrode 6. The plating layer is formed through, for example, electroplating. The plating layer has a layer structure including a Cu plating layer, a Ni plating layer, and a Sn plating layer, or a layer structure including a Ni plating layer and a Sn plating layer, or the like.

The first terminal electrode 3 constitutes an input terminal (a terminal to which a signal is input). The second terminal electrode 4 constitutes an output terminal (a terminal to which a signal is output). The third terminal electrode 5 constitutes a ground terminal (a terminal connected to the ground). The fourth terminal electrode 6 constitutes a ground terminal.

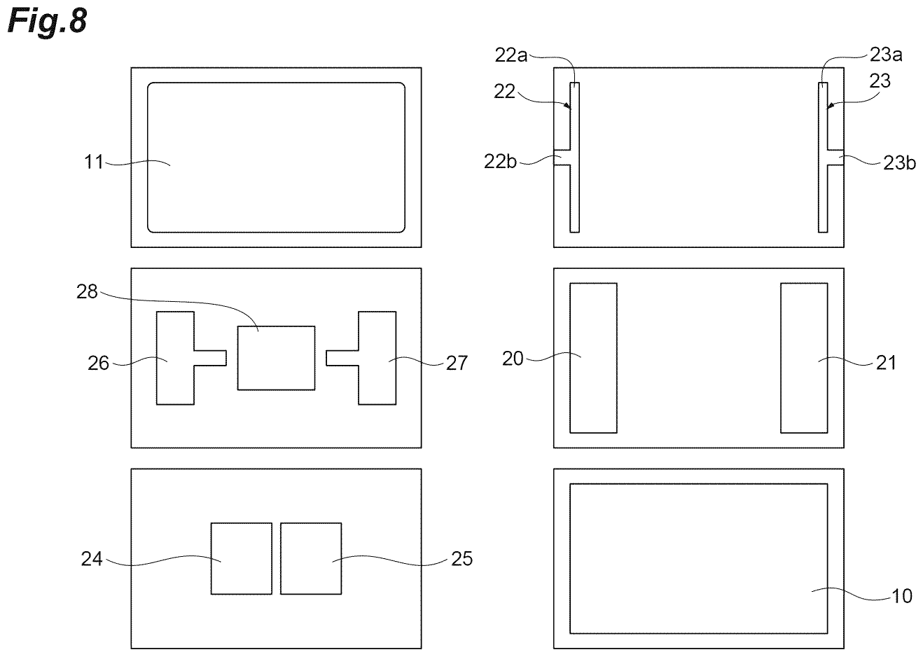

FIG. 8 is a view illustrating conductors included in the electronic component 1. As illustrated in FIGS. 2 to 8, the electronic component 1 includes, in the element body 2, a first ground conductor 10, a second ground conductor 11, a first conductor 12, a second conductor 13, a third conductor 14, a fourth conductor 15, a fifth conductor (“first conductor” in the claims) 16, a sixth conductor (“second conductor” in the claims) 17, a seventh conductor (“third conductor” in the claims) 18, an eighth conductor (“fourth conductor” in the claims) 19, a connection conductor 20, a connection conductor 21, a connection conductor 22, a connection conductor 23, a capacitor conductor 24, a capacitor conductor 25, a capacitor conductor 26, a capacitor conductor 27, and a capacitor conductor 28.

Each conductor may contain a conductive material (for example, Ag or Pd or the like). Each conductor may be configured as a sintered body of a conductive paste containing a conductive material (for example, Ag powder or Pd powder or the like).

The first ground conductor 10 is disposed at a position closer to the main surface 2c. The first ground conductor 10 has a substantially rectangular shape. The first ground conductor 10 is electrically connected to the third terminal electrode 5 (first portion 5a) by a plurality of connection conductors 29. The plurality of connection conductors 29 are disposed at a predetermined interval in the first direction D1. The first ground conductor 10 is electrically connected to the fourth terminal electrode 6 (first portion 6a) by a plurality of connection conductors 30.

The plurality of connection conductors 30 are disposed at a predetermined interval in the first direction D1.

The second ground conductor 11 is disposed at a position closer to the main surface 2d. The second ground conductor 11 has a substantially rectangular shape. The second ground conductor 11 is electrically connected to the third terminal electrode 5 (second portion 5b) by a plurality of connection conductors 31. The plurality of connection conductors 31 are disposed at a predetermined interval in the first direction D1. The second ground conductor 11 is electrically connected to the fourth terminal electrode 6 (second portion 6b) by a plurality of connection conductors 32. The plurality of connection conductors 32 are disposed at a predetermined interval in the first direction D1.

The first conductor 12 extends along the second direction D2. The first conductor 12 can include a plurality of via conductors. The first conductor 12 is disposed at a position on the end surface 2a side and the side surface 2e side of the element body 2 (corner portion formed by the end surface 2a and the side surface 2e). A part of the first conductor 12 is disposed at a position overlapping the third terminal electrode 5 and the fourth terminal electrode 6 as viewed from the third direction D3. An end portion of the first conductor 12 on the main surface 2c side is connected to the first ground conductor 10. An end portion of the first conductor 12 on the main surface 2d side is connected to the second ground conductor 11.

The second conductor 13 extends along the second direction D2. The second conductor 13 can include a plurality of via conductors. The second conductor 13 is disposed at a position on the end surface 2b side and the side surface 2e side of the element body 2 (corner portion formed by the end surface 2b and the side surface 2e). A part of the second conductor 13 is disposed at a position overlapping the third terminal electrode 5 and the fourth terminal electrode 6 as viewed from the third direction D3. An end portion of the second conductor 13 on the main surface 2c side is connected to the first ground conductor 10. An end portion of the second conductor 13 on the main surface 2d side is connected to the second ground conductor 11.

The third conductor 14 extends along the second direction D2. The third conductor 14 can include a plurality of via conductors. The third conductor 14 is disposed at a position on the end surface 2a side and the side surface 2f side of the element body 2 (corner portion formed by the end surface 2a and the side surface 2f). A part of the third conductor 14 is disposed at a position overlapping the third terminal electrode 5 and the fourth terminal electrode 6 as viewed from the third direction D3. An end portion of the third conductor 14 on the main surface 2c side is connected to the first ground conductor 10. An end portion of the third conductor 14 on the main surface 2d side is connected to the second ground conductor 11.

The fourth conductor 15 extends along the second direction D2. The fourth conductor 15 can include a plurality of via conductors. The fourth conductor 15 is disposed at a position on the end surface 2b side and the side surface 2f side of the element body 2 (corner portion formed by the end surface 2b and the side surface 2f). A part of the fourth conductor 15 is disposed at a position overlapping the third terminal electrode 5 and the fourth terminal electrode 6 as viewed from the third direction D3. An end portion of the fourth conductor 15 on the main surface 2c side is connected to the first ground conductor 10. An end portion of the fourth conductor 15 on the main surface 2d side is connected to the second ground conductor 11.

The fifth conductor 16 extends along the second direction D2. The fifth conductor 16 can include a plurality of via conductors. The fifth conductor 16 is disposed in the central region of the element body 2 as viewed from the second direction D2. Specifically, the fifth conductor 16 is disposed on the end surface 2a side with respect to the center in the first direction D1 at the central position in the third direction D3 of the element body 2 as viewed from the second direction D2. The fifth conductor 16 is disposed at a position overlapping the third terminal electrode 5 and the fourth terminal electrode 6 as viewed from the third direction D3. An end portion (one end) of the fifth conductor 16 on the main surface 2c side is connected to the first ground conductor 10. An end portion (the other end) of the fifth conductor 16 on the main surface 2d side is connected to the capacitor conductor 24.

The sixth conductor 17 extends along the second direction D2. The sixth conductor 17 can include a plurality of via conductors. The sixth conductor 17 is disposed in the central region of the element body 2 as viewed from the second direction D2. Specifically, the sixth conductor 17 is disposed on the end surface 2b side with respect to the center in the first direction D1 at the central position in the third direction D3 of the element body 2 as viewed from the second direction D2. The sixth conductor 17 is disposed at a position overlapping the third terminal electrode 5 and the fourth terminal electrode 6 as viewed from the third direction D3. An end portion of the sixth conductor 17 on the main surface 2c side is connected to the first ground conductor 10. An end portion of the sixth conductor 17 on the main surface 2d side is connected to the capacitor conductor 25.

The seventh conductor 18 extends along the second direction D2. The seventh conductor 18 can include a plurality of via conductors. The seventh conductor 18 is disposed on the end surface 2a side at the central position in the third direction D3 of the element body 2. The seventh conductor 18 is disposed at a position overlapping the third terminal electrode 5 and the fourth terminal electrode 6 as viewed from the third direction D3. An end portion of the seventh conductor 18 on the main surface 2c side is connected to the connection conductor 20. An end portion of the seventh conductor 18 on the main surface 2d side is connected to the capacitor conductor 26.

The eighth conductor 19 extends along the second direction D2. The eighth conductor 19 can include a plurality of via conductors. The eighth conductor 19 is disposed on the end surface 2b side at the central position in the third direction D3 of the element body 2. The eighth conductor 19 is disposed at a position overlapping the third terminal electrode 5 and the fourth terminal electrode 6 as viewed from the third direction D3. An end portion of the eighth conductor 19 on the main surface 2c side is connected to the connection conductor 21. An end portion of the eighth conductor 19 on the main surface 2d side is connected to the capacitor conductor 27.

The first conductor 12 and the second conductor 13 are disposed on the same straight line in the first direction D1. The third conductor 14 and the fourth conductor 15 are disposed on the same straight line in the first direction D1. The first conductor 12 and the third conductor 14 are disposed at positions facing each other in the third direction D3. The second conductor 13 and the fourth conductor 15 are disposed at positions facing each other in the third direction D3.

The fifth conductor 16, the sixth conductor 17, the seventh conductor 18, and the eighth conductor 19 are disposed on the same straight line in the first direction D1. The fifth conductor 16 and the sixth conductor 17 are disposed at a predetermined interval in the first direction D1. The fifth conductor 16 and the seventh conductor 18 are disposed at a predetermined interval in the first direction D1. The sixth conductor 17 and the eighth conductor 19 are disposed at a predetermined interval in the first direction D1. The seventh conductor 18 is disposed between the first conductor 12 and the third conductor 14 in the third direction D3. The eighth conductor 19 is disposed between the second conductor 13 and the fourth conductor 15 in the third direction D3.

The connection conductor 20 connects the first conductor 12 and the third conductor 14. The connection conductor 20 is connected to a central portion of the second direction D2 in the first conductor 12 and the third conductor 14. The connection conductor 20 extends along the third direction D3. The connection conductor 20 has a plate shape and a rectangular shape.

The connection conductor 21 connects the second conductor 13 and the fourth conductor 15. The connection conductor 21 is connected to a central portion of the second direction D2 in the second conductor 13 and the fourth conductor 15. The connection conductor 21 extends along the third direction D3. The connection conductor 21 has a plate shape and a rectangular shape.

The connection conductor 22 connects the first terminal electrode 3 to the first conductor 12 and the third conductor 14. The connection conductor 22 has a T shape. The connection conductor 22 includes a first portion 22a extending along the third direction D3, and a second portion 22b extending along the first direction D1. The first portion 22a is connected to a central portion of the second direction D2 (a position closer to the main surface 2d side than the connection conductor 20) in the first conductor 12 and the third conductor 14. The second portion 22b is connected to the first portion 3a of the first terminal electrode 3.

The connection conductor 23 connects the second terminal electrode 4 to the second conductor 13 and the fourth conductor 15. The connection conductor 23 has a T shape. The connection conductor 23 includes a first portion 23a extending along the third direction D3, and a second portion 23b extending along the first direction D1. The first portion 23a is connected to a central portion of the second direction D2 (a position closer to the main surface 2d side than the connection conductor 21) in the second conductor 13 and the fourth conductor 15. The second portion 23b is connected to the first portion 4a of the second terminal electrode 4.

The capacitor conductor 24 is connected to the fifth conductor 16. The capacitor conductor 24 has a rectangular shape. The capacitor conductor 25 is connected to the sixth conductor 17. The capacitor conductor 25 has a rectangular shape. The capacitor conductor 24 and the capacitor conductor 25 are arranged side by side in the first direction D1.

The capacitor conductor 26 is connected to the seventh conductor 18. The capacitor conductor 26 has a T shape. The capacitor conductor 26 is disposed at a position facing each of the second ground conductor 11 and the capacitor conductor 24. That is, the capacitor conductor 26 is disposed between the second ground conductor 11 and the capacitor conductor 24 in the second direction D2.

The capacitor conductor 27 is connected to the eighth conductor 19. The capacitor conductor 27 has a T shape. The capacitor conductor 27 is disposed at a position facing each of the second ground conductor 11 and the capacitor conductor 25. That is, the capacitor conductor 27 is disposed between the second ground conductor 11 and the capacitor conductor 25 in the second direction D2.

The capacitor conductor 28 has a rectangular shape. The capacitor conductor 28 is disposed at the same height position as the capacitor conductor 26 and the capacitor conductor 27 in the second direction D2. The capacitor conductor 28 is disposed between the capacitor conductor 26 and the capacitor conductor 27 in the first direction D1. The capacitor conductor 28 is disposed at a position facing each of the second ground conductor 11, the capacitor conductor 24, and the capacitor conductor 25. That is, the capacitor conductor 28 is disposed between the second ground conductor 11 and the capacitor conductor 24 and between the second ground conductor 11 and the capacitor conductor 25 in the second direction D2.

The fifth conductor 16 and the capacitor conductor 24 constitute the first resonator K1. The sixth conductor 17 and the capacitor conductor 25 constitute the second resonator K2. The seventh conductor 18 and the capacitor conductor 26 constitute the third resonator K3. The eighth conductor 19 and the capacitor conductor 27 constitute the fourth resonator K4.

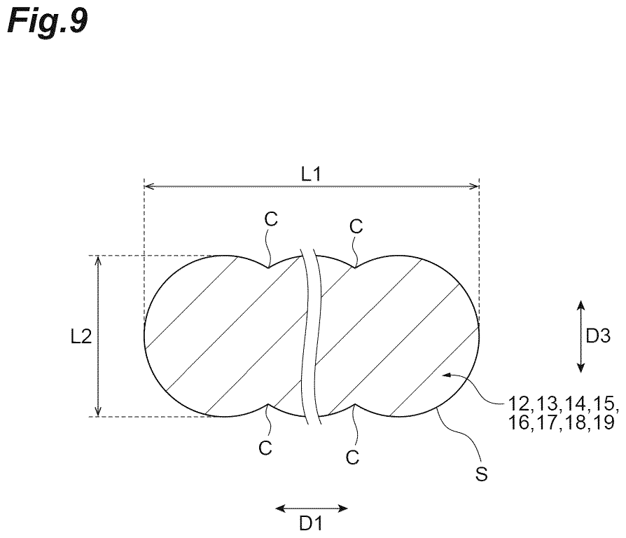

FIG. 9 is a diagram illustrating a cross-sectional configuration of the conductor (the first conductor 12, the second conductor 13, the third conductor 14, the fourth conductor 15, the fifth conductor 16, the sixth conductor 17, the seventh conductor 18, and the eighth conductor 19). The cross section of each of the first conductor 12, the second conductor 13, the third conductor 14, the fourth conductor 15, the fifth conductor 16, the sixth conductor 17, the seventh conductor 18, and the eighth conductor 19 illustrated in FIG. 9 is a cross section in a plane along the first direction D1 and the third direction D3. As illustrated in FIG. 9, for the first conductor 12, the second conductor 13, the third conductor 14, the fourth conductor 15, the fifth conductor 16, the sixth conductor 17, the seventh conductor 18, and the eighth conductor 19, a length L1 in the first direction D1 is longer than a length L2 in the third direction D3 (L1>L2) when viewed from the second direction D2.

The first conductor 12, the second conductor 13, the third conductor 14, the fourth conductor 15, the fifth conductor 16, the sixth conductor 17, the seventh conductor 18, and the eighth conductor 19 are disposed such that the length L1 is along the first direction D1 and the length L2 is along the third direction D3. That is, the extending direction of the first conductor 12, the second conductor 13, the third conductor 14, the fourth conductor 15, the fifth conductor 16, the sixth conductor 17, the seventh conductor 18, and the eighth conductor 19 is the first direction D1. The first conductor 12, the second conductor 13, the third conductor 14, the fourth conductor 15, the fifth conductor 16, the sixth conductor 17, the seventh conductor 18, and the eighth conductor 19 are along the longitudinal direction of the element body 2 and the extending direction of the third terminal electrode 5 and the fourth terminal electrode 6.

In the present embodiment, each of the first conductor 12, the second conductor 13, the third conductor 14, the fourth conductor 15, the fifth conductor 16, the sixth conductor 17, the seventh conductor 18, and the eighth conductor 19 has a shape in which a plurality of circles overlap. Specifically, each of the first conductor 12, the second conductor 13, the third conductor 14, the fourth conductor 15, the fifth conductor 16, the sixth conductor 17, the seventh conductor 18, and the eighth conductor 19 has a shape in which parts of a pair of adjacent circles overlap. For example, two adjacent circles overlap such that the outer periphery of one circle passes through the center of the other circle.

A plurality of recesses C are provided on each side surface S of the first conductor 12, the second conductor 13, the third conductor 14, the fourth conductor 15, the fifth conductor 16, the sixth conductor 17, the seventh conductor 18, and the eighth conductor 19. The recesses C extend in the second direction D2. The recesses C are disposed at a predetermined interval in the first direction D1. The recesses C are disposed at positions facing each other in the third direction D3.

In the electronic component 1, the fifth conductor 16 extends in a direction in which the first resonator K1, the second resonator K2, the third resonator K3, and the fourth resonator K4 are arranged side by side as viewed from the second direction D2. In the present embodiment, the arranged direction is an extending direction of a region where the first resonator K1, the second resonator K2, the third resonator K3, and the fourth resonator K4 are disposed. For example, when the first resonator K1, the second resonator K2, the third resonator K3, and the fourth resonator K4 are disposed in a staggered manner, the extending direction of the region including the first resonator K1, the second resonator K2, the third resonator K3, and the fourth resonator K4 is the direction in which the first resonator K1, the second resonator K2, the third resonator K3, and the fourth resonator K4 are arranged side by side. In the present embodiment, the first resonator K1, the second resonator K2, the third resonator K3, and the fourth resonator K4 are linearly disposed, and the direction in which the first resonator K1, the second resonator K2, the third resonator K3, and the fourth resonator K4 are arranged side by side is the first direction D1. Therefore, the fifth conductor 16 extends in the first direction D1.

In the electronic component 1, the third resonator K3, the first resonator K1, the second resonator K2, and the fourth resonator K4 are disposed in order from the end surface 2a side to the end surface 2b side in the first direction D1. That is, the first resonator K1 is disposed between the second resonator K2 and the third resonator K3 in the first direction D1. The second resonator K2 is disposed between the first resonator K1 and the fourth resonator K4.

The first resonator K1 (the fifth conductor 16) and the second resonator K2 (the sixth conductor 17) are electromagnetically coupled. The first resonator K1 (the fifth conductor 16) and the third resonator K3 (the seventh conductor 18) are electromagnetically coupled. The second resonator K2 (the sixth conductor 17) and the fourth resonator K4 (the eighth conductor 19) are electromagnetically coupled. In the electronic component 1, the strength of electromagnetic coupling can be adjusted by adjusting distances among the first resonator K1 (the fifth conductor 16), the second resonator K2 (the sixth conductor 17), the third resonator K3 (the seventh conductor 18), and the fourth resonator K4 (the eighth conductor 19) and/or a length of each of the fifth conductor 16 and the sixth conductor 17 in the first direction D1.

As described above, in the electronic component 1 according to the present embodiment, as viewed from the second direction D2, the length L1 in the first direction D1 of each of the first conductor 12, the second conductor 13, the third conductor 14, the fourth conductor 15, the fifth conductor 16, the sixth conductor 17, the seventh conductor 18, and the eighth conductor 19 is longer than the length L2 in the third direction D3 of the first conductor 12, the second conductor 13, the third conductor 14, the fourth conductor 15, the fifth conductor 16, the sixth conductor 17, the seventh conductor 18, and the eighth conductor 19 (L1>L2). As a result, in the electronic component 1, since the cross-sectional areas of the first conductor 12, the second conductor 13, the third conductor 14, the fourth conductor 15, the fifth conductor 16, the sixth conductor 17, the seventh conductor 18, and the eighth conductor 19 can be increased, the resistance values of the first conductor 12, the second conductor 13, the third conductor 14, the fourth conductor 15, the fifth conductor 16, the sixth conductor 17, the seventh conductor 18, and the eighth conductor 19 can be decreased, and a Q factor can be improved.

In the electronic component 1, the fifth conductor 16 extends in a direction in which the first resonator K1, the second resonator K2, the third resonator K3, and the fourth resonator K4 are arranged side by side as viewed from the second direction D2. In this configuration, in the electronic component 1, the first resonator K1 is disposed between the second resonator K2 and the third resonator K3. As a result, in the electronic component 1, the electromagnetic coupling between the first resonator K1 and the second resonator K2 and the electromagnetic coupling between the first resonator K1 and the third resonator K3 can be adjusted by adjusting a position of the first resonator K1 with respect to each of the second resonator K2 and the third resonator K3. As described above, in the electronic component 1, the electromagnetic coupling can be adjusted by the position of the first resonator K1 provided between the second resonator K2 and the third resonator K3.

Therefore, in the electronic component 1, the adjustment of the electromagnetic coupling can be simplified.

The length of the element body 2 in the first direction D1 is longer than the length of the element body 2 in the third direction D3, and the third terminal electrode 5 and the fourth terminal electrode 6 connected to the ground are disposed on the pair of side surfaces 2e and 2f of the element body 2. In this configuration, as viewed from the second direction D2, the length L1 in the first direction D1 of each of the fifth conductor 16, the sixth conductor 17, the seventh conductor 18, and the eighth conductor 19 is longer than the length L2 in the third direction D3 of each of the fifth conductor 16, the sixth conductor 17, the seventh conductor 18, and the eighth conductor 19. As described above, in the electronic component 1, since the fifth conductor 16, the sixth conductor 17, the seventh conductor 18, and the eighth conductor 19 extend along the longitudinal direction of the element body 2, the distance from each of the third terminal electrode 5 and the fourth terminal electrode 6 can be secured. As a result, in the electronic component 1, a space formed between each of the fifth conductor 16, the sixth conductor 17, the seventh conductor 18, and the eighth conductor 19 and each of the third terminal electrode 5 and the fourth terminal electrode 6 can be secured. Thus, in the electronic component 1, a region where a magnetic flux is generated can be secured, and a magnetic field can be formed around the fifth conductor 16, the sixth conductor 17, the seventh conductor 18, and the eighth conductor 19. Therefore, in the electronic component 1, since the generation of the eddy current can be suppressed, the generation of the loss caused by the eddy current can be suppressed. As a result, the Q factor can be improved in the electronic component 1.

### Second Embodiment

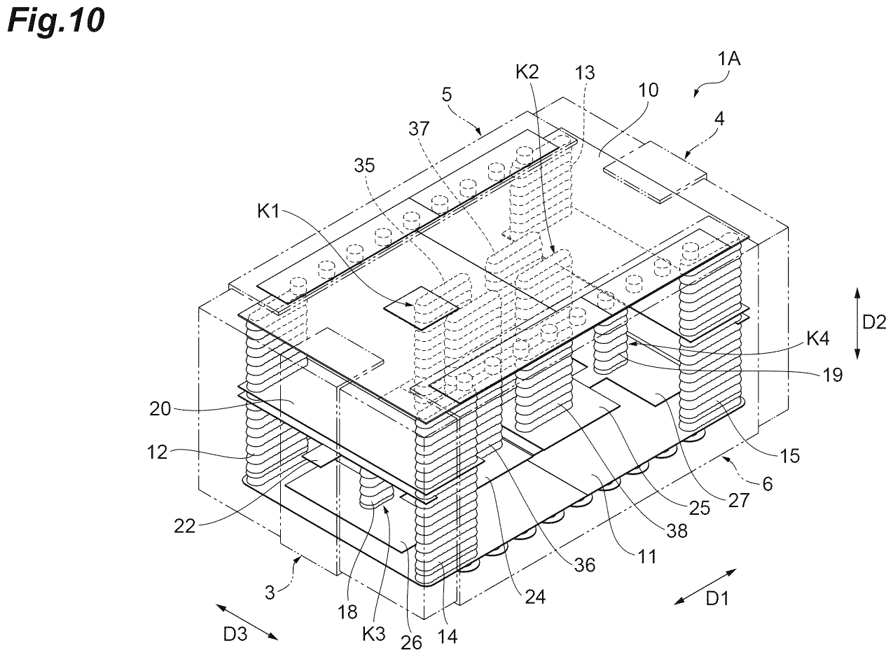

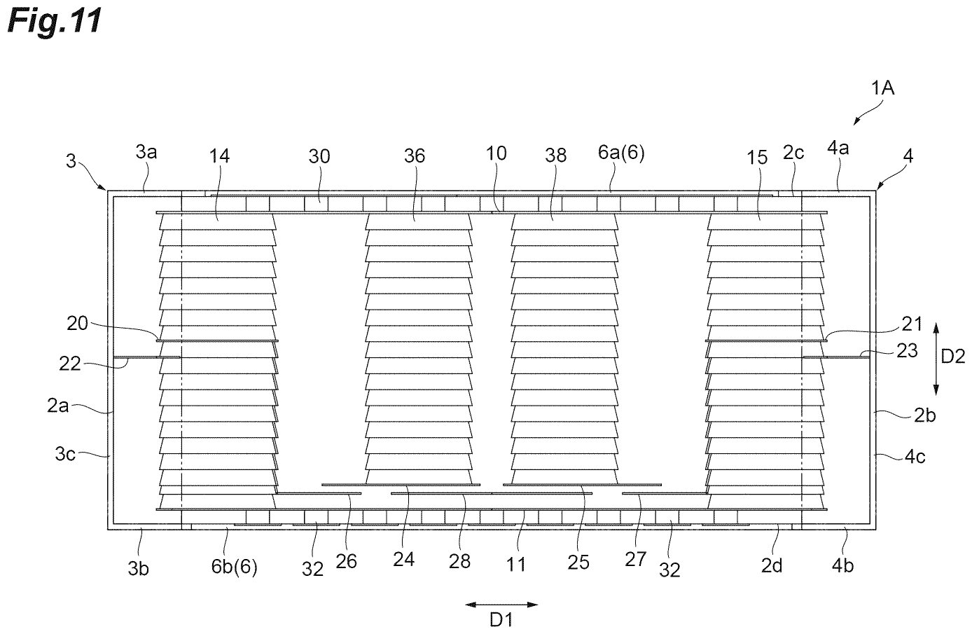

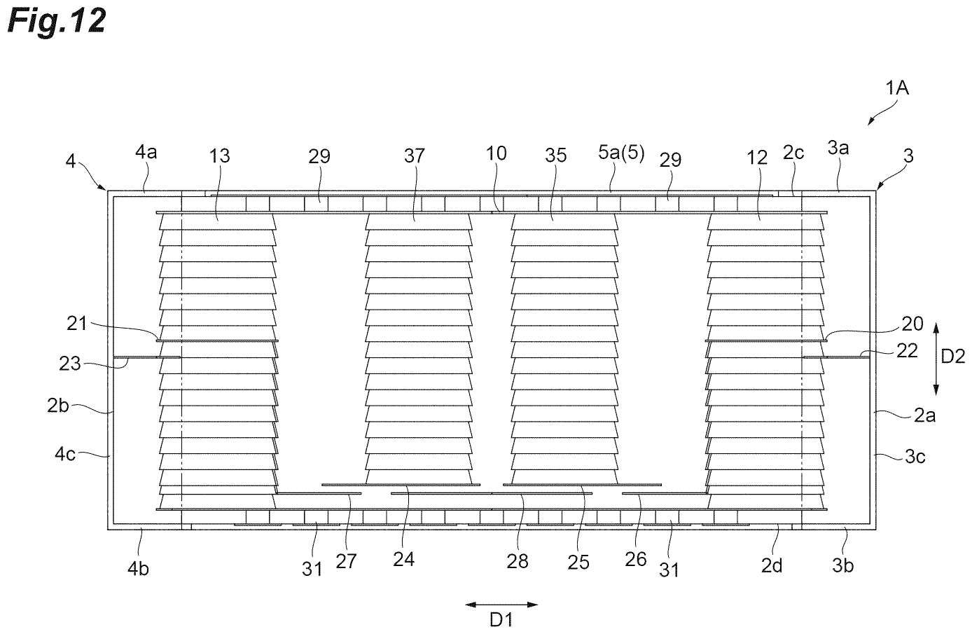

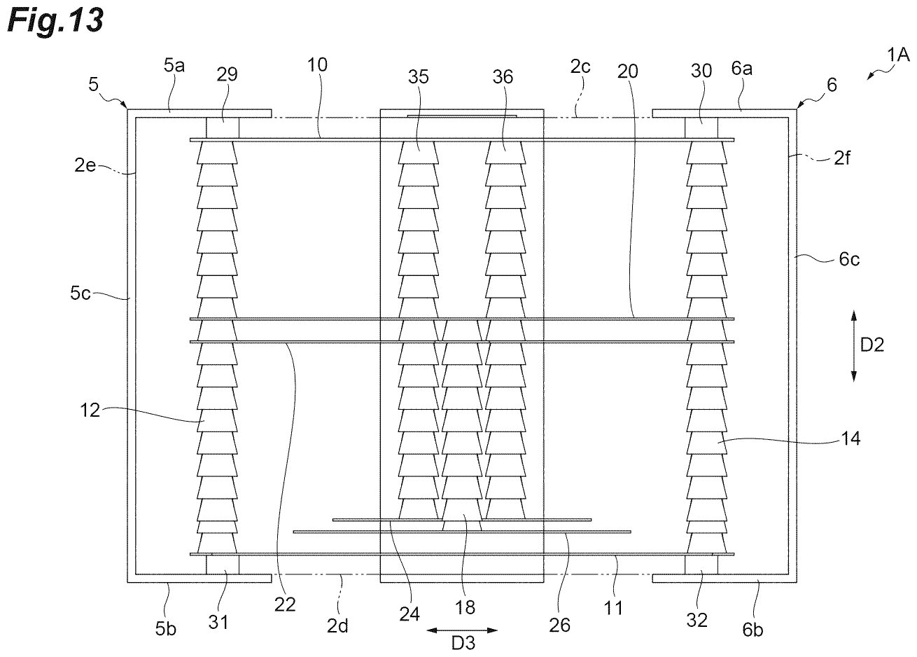

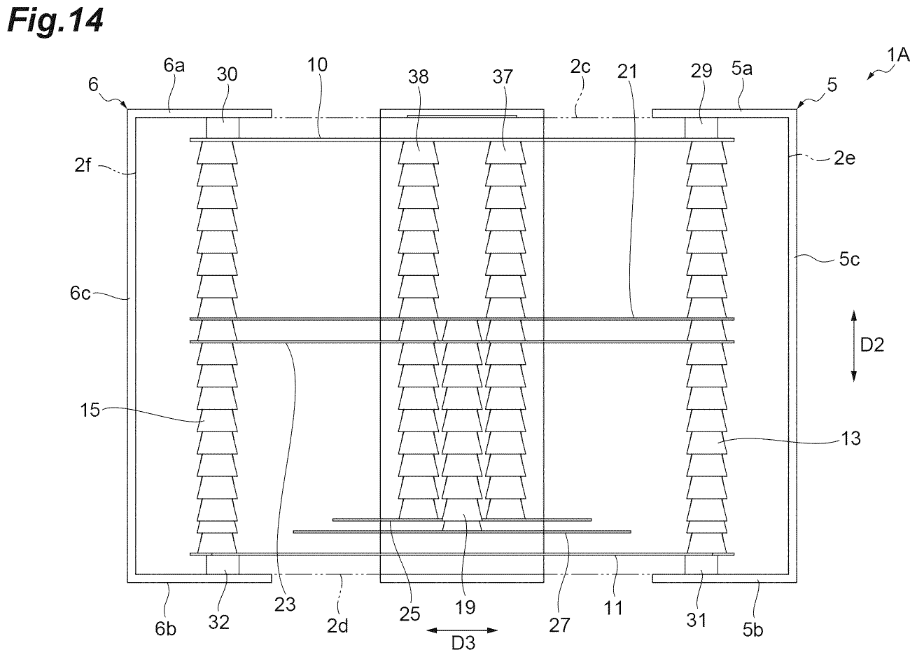

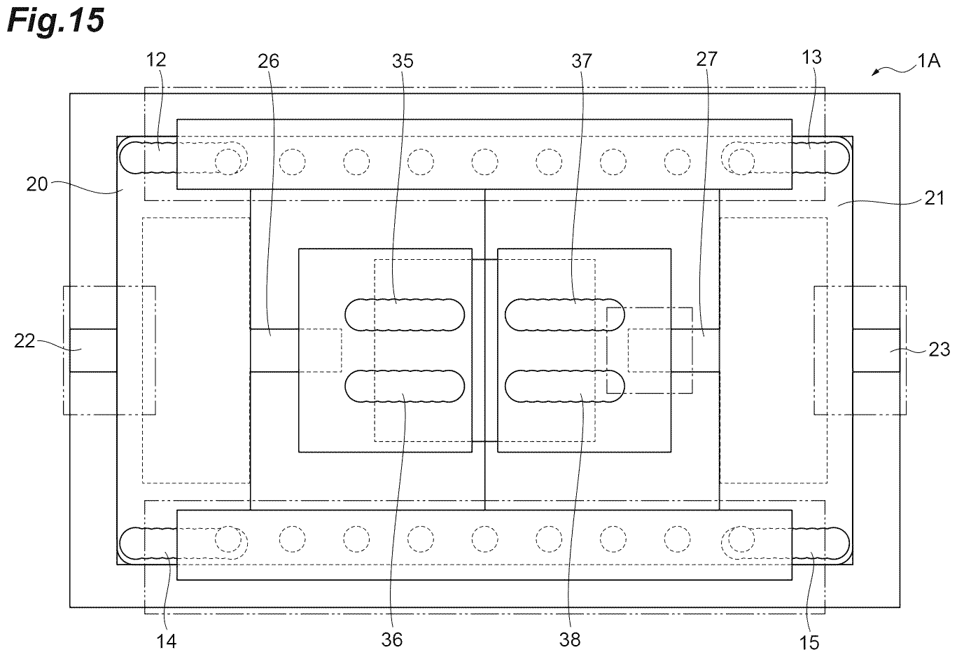

Next, a second embodiment will be described. FIG. 10 is a transparent perspective view of an electronic component according to a second embodiment. FIG. 11 is a view of the electronic component illustrated in FIG. 10 as viewed from a side of one side surface. FIG. 12 is a view of the electronic component illustrated in FIG. 10 as viewed from a side of the other side surface. FIG. 13 is a view of the electronic component illustrated in FIG. 10 as viewed from a side of one end surface. FIG. 14 is a view of the electronic component illustrated in FIG. 10 as viewed from a side of the other end surface. FIG. 15 is a view of the electronic component illustrated in FIG. 10 as viewed from a side of one main surface. As illustrated in FIGS. 10 to 15, an electronic component 1A includes an element body 2, a first terminal electrode 3, a second terminal electrode 4, a third terminal electrode 5, and a fourth terminal electrode 6, which are respectively disposed on the element body 2, a first resonator K1, a second resonator K2, a third resonator K3, and a fourth resonator K4.

As illustrated in FIGS. 10 to 15, the electronic component 1A includes, in the element body 2, a first ground conductor 10, a second ground conductor 11, a first conductor 12, a second conductor 13, a third conductor 14, a fourth conductor 15, a seventh conductor 18, an eighth conductor 19, a connection conductor 20, a connection conductor 21, a connection conductor 22, a connection conductor 23, a capacitor conductor 24, a capacitor conductor 25, a capacitor conductor 26, a capacitor conductor 27, and a capacitor conductor 28. The electronic component 1A includes a tenth conductor 35, an eleventh conductor 36, a twelfth conductor 37, and a thirteenth conductor 38.

The tenth conductor 35 extends along the second direction D2.

The tenth conductor 35 can include a plurality of via conductors. The tenth conductor 35 is disposed in the central region of the element body 2 as viewed from the second direction D2. Specifically, the tenth conductor 35 is disposed on the end surface 2a side with respect to the center in the first direction D1 at a position on the side surface 2e side with respect to the center in the third direction D3 of the element body 2 as viewed from the second direction D2. The tenth conductor 35 is disposed at a position overlapping the third terminal electrode 5 and the fourth terminal electrode 6 as viewed from the third direction D3. An end portion of the tenth conductor 35 on the main surface 2c side is connected to the first ground conductor 10. An end portion of the tenth conductor 35 on the main surface 2d side is connected to the capacitor conductor 24.

The eleventh conductor 36 extends along the second direction D2. The eleventh conductor 36 can include a plurality of via conductors.

The eleventh conductor 36 is disposed in the central region of the element body 2 as viewed from the second direction D2. Specifically, the eleventh conductor 36 is disposed on the end surface 2a side with respect to the center in the first direction D1 at a position on the side surface 2f side with respect to the center in the third direction D3 of the element body 2 as viewed from the second direction D2. The eleventh conductor 36 is disposed at a position overlapping the third terminal electrode 5 and the fourth terminal electrode 6 as viewed from the third direction D3. An end portion of the eleventh conductor 36 on the main surface 2c side is connected to the first ground conductor 10. An end portion of the eleventh conductor 36 on the main surface 2d side is connected to the capacitor conductor 24.

The twelfth conductor 37 extends along the second direction D2. The twelfth conductor 37 can include a plurality of via conductors. The twelfth conductor 37 is disposed in the central region of the element body 2 as viewed from the second direction D2. Specifically, the twelfth conductor 37 is disposed on the end surface 2b side with respect to the center in the first direction D1 at a position on the side surface 2e side with respect to the center in the third direction D3 of the element body 2 as viewed from the second direction D2. The twelfth conductor 37 is disposed at a position overlapping the third terminal electrode 5 and the fourth terminal electrode 6 as viewed from the third direction D3. An end portion of the twelfth conductor 37 on the main surface 2c side is connected to the first ground conductor 10. An end portion of the twelfth conductor 37 on the main surface 2d side is connected to the capacitor conductor 25.

The thirteenth conductor 38 extends along the second direction D2. The thirteenth conductor 38 can include a plurality of via conductors. The thirteenth conductor 38 is disposed in the central region of the element body 2 as viewed from the second direction D2. Specifically, the thirteenth conductor 38 is disposed on the end surface 2b side with respect to the center in the first direction D1 at a position on the side surface 2f side with respect to the center in the third direction D3 of the element body 2 as viewed from the second direction D2. The thirteenth conductor 38 is disposed at a position overlapping the third terminal electrode 5 and the fourth terminal electrode 6 as viewed from the third direction D3. An end portion of the thirteenth conductor 38 on the main surface 2c side is connected to the first ground conductor 10. An end portion of the thirteenth conductor 38 on the main surface 2d side is connected to the capacitor conductor 25.

The tenth conductor 35 and the eleventh conductor 36 are arranged side by side in the third direction D3. The tenth conductor 35 and the eleventh conductor 36 are disposed at a predetermined interval in the third direction D3. The twelfth conductor 37 and the thirteenth conductor 38 are arranged side by side in the third direction D3. The twelfth conductor 37 and the thirteenth conductor 38 are disposed at a predetermined interval in the third direction D3.

The tenth conductor 35 and the twelfth conductor 37 are disposed on the same straight line in the first direction D1. The tenth conductor 35 and the twelfth conductor 37 are disposed at a predetermined interval in the first direction D1. The eleventh conductor 36 and the thirteenth conductor 38 are disposed on the same straight line in the first direction D1. The eleventh conductor 36 and the thirteenth conductor 38 are disposed at a predetermined interval in the first direction D1.

The tenth conductor 35, the eleventh conductor 36, and the capacitor conductor 24 constitute the first resonator K1. The twelfth conductor 37, the thirteenth conductor 38, and the capacitor conductor 25 constitute the second resonator K2. The seventh conductor 18 and the capacitor conductor 26 constitute the third resonator K3. The eighth conductor 19 and the capacitor conductor 27 constitute the fourth resonator K4.

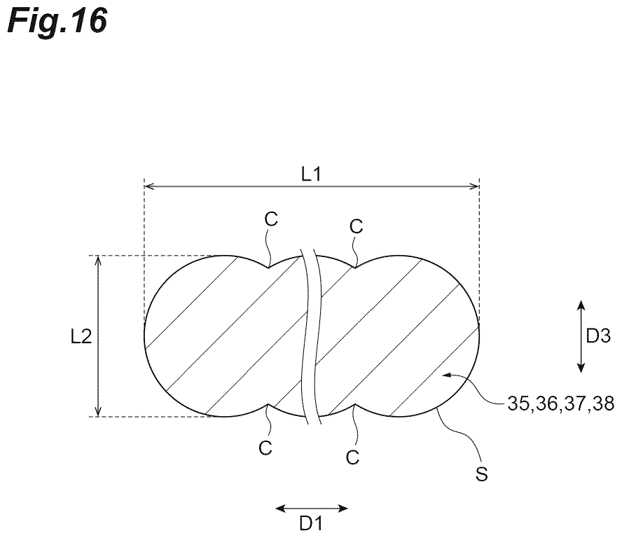

FIG. 16 is a diagram illustrating a cross-sectional configuration of the conductor (the tenth conductor 35, the eleventh conductor 36, the twelfth conductor 37, and the thirteenth conductor 38). The cross section of each of the tenth conductor 35, the eleventh conductor 36, the twelfth conductor 37, and the thirteenth conductor 38 illustrated in FIG. 16 is a cross section in a plane along the first direction D1 and the third direction D3. As illustrated in FIG. 16, for the tenth conductor 35, the eleventh conductor 36, the twelfth conductor 37, and the thirteenth conductor 38, the length L1 in the first direction D1 is longer than the length L2 in the third direction D3 (L1>L2) when viewed from the second direction D2.

The tenth conductor 35, the eleventh conductor 36, the twelfth conductor 37, and the thirteenth conductor 38 are disposed such that the length L1 is along the first direction D1 and the length L2 is along the third direction D3. That is, the extending direction of the tenth conductor 35, the eleventh conductor 36, the twelfth conductor 37, and the thirteenth conductor 38 is the first direction D1. The tenth conductor 35, the eleventh conductor 36, the twelfth conductor 37, and the thirteenth conductor 38 are along the longitudinal direction of the element body 2 and the extending direction of the third terminal electrode 5 and the fourth terminal electrode 6.

In the present embodiment, each of the tenth conductor 35, the eleventh conductor 36, the twelfth conductor 37, and the thirteenth conductor 38 has a shape in which a plurality of circles overlap. Specifically, each of the tenth conductor 35, the eleventh conductor 36, the twelfth conductor 37, and the thirteenth conductor 38 has a shape in which parts of a pair of adjacent circles overlap. For example, two adjacent circles overlap such that the outer periphery of one circle passes through the center of the other circle.

A plurality of recesses C are provided on each side surface S of the tenth conductor 35, the eleventh conductor 36, the twelfth conductor 37, and the thirteenth conductor 38. The recesses C extend in the second direction D2. The recesses C are disposed at a predetermined interval in the first direction D1. The recesses C are disposed at positions facing each other in the third direction D3.

In the electronic component 1A, the tenth conductor 35 and the eleventh conductor 36 extend in a direction in which the first resonator K1, the second resonator K2, the third resonator K3, and the fourth resonator K4 are arranged side by side as viewed from the second direction D2. In the present embodiment, the arranged direction is an extending direction of a region where the first resonator K1, the second resonator K2, the third resonator K3, and the fourth resonator K4 are disposed. For example, when the first resonator K1, the second resonator K2, the third resonator K3, and the fourth resonator K4 are disposed in a staggered manner, the extending direction of the region including the first resonator K1, the second resonator K2, the third resonator K3, and the fourth resonator K4 is the direction in which the first resonator K1, the second resonator K2, the third resonator K3, and the fourth resonator K4 are arranged side by side. In the present embodiment, the direction in which the first resonator K1, the second resonator K2, the third resonator K3, and the fourth resonator K4 are arranged is the first direction D1. Therefore, the tenth conductor 35 and the eleventh conductor 36 extend in the first direction D1.

In the electronic component 1A, the third resonator K3, the first resonator K1, the second resonator K2, and the fourth resonator K4 are disposed in order from the end surface 2a side to the end surface 2b side in the first direction D1. That is, the first resonator K1 is disposed between the second resonator K2 and the third resonator K3 in the first direction D1. The second resonator K2 is disposed between the first resonator K1 and the fourth resonator K4.

The first resonator K1 (the tenth conductor 35 and the eleventh conductor 36) and the second resonator K2 (the twelfth conductor 37 and the thirteenth conductor 38) are electromagnetically coupled. The first resonator K1 (the tenth conductor 35 and the eleventh conductor 36) and the third resonator K3 (the seventh conductor 18) are electromagnetically coupled. The second resonator K2 (the twelfth conductor 37 and the thirteenth conductor 38) and the fourth resonator K4 (the eighth conductor 19) are electromagnetically coupled. In the electronic component 1A, strength of electromagnetic coupling can be adjusted by adjusting distances among the first resonator K1 (the tenth conductor 35 and the eleventh conductor 36), the second resonator K2 (the twelfth conductor 37 and the thirteenth conductor 38), the third resonator K3 (the seventh conductor 18), and the fourth resonator K4 (the eighth conductor 19) and/or a length of each of the tenth conductor 35 and the eleventh conductor 36, the twelfth conductor 37, and the thirteenth conductor 38 in the first direction D1. In the electronic component 1A, the strength of the electromagnetic coupling can be adjusted by adjusting the distance between the tenth conductor 35 and the eleventh conductor 36 and the distance between the twelfth conductor 37 and the thirteenth conductor 38.

As described above, in the electronic component 1A according to the present embodiment, the tenth conductor 35 and the eleventh conductor 36 extend in a direction in which the first resonator K1, the second resonator K2, the third resonator K3, and the fourth resonator K4 are arranged side by side as viewed from the second direction D2. In this configuration, in the electronic component 1A, the first resonator K1 is disposed between the second resonator K2 and the third resonator K3.

As a result, in the electronic component 1A, the electromagnetic coupling between the first resonator K1 and the second resonator K2 and the electromagnetic coupling between the first resonator K1 and the third resonator K3 can be adjusted by adjusting a position of the first resonator K1 with respect to each of the second resonator K2 and the third resonator K3. As described above, in the electronic component 1A, the electromagnetic coupling can be adjusted by the position of the first resonator K1 provided between the second resonator K2 and the third resonator K3. Therefore, in the electronic component 1A, the adjustment of the electromagnetic coupling can be simplified.

In the electronic component 1A, the length of the element body 2 in the first direction D1 is longer than the length of the element body 2 in the third direction D3, and the third terminal electrode 5 and the fourth terminal electrode 6 connected to the ground are disposed on the pair of side surfaces 2e and 2f of the element body 2. In this configuration, as viewed from the second direction D2, the length L1 in the first direction D1 of each of the seventh conductor 18, the eighth conductor 19, the tenth conductor 35, the eleventh conductor 36, the twelfth conductor 37, and the thirteenth conductor 38 is longer than the length L2 in the third direction D3 of each of the fifth conductor 16, the sixth conductor 17, the seventh conductor 18, and the eighth conductor 19. As described above, in the electronic component 1A, since the seventh conductor 18, the eighth conductor 19, the tenth conductor 35, the eleventh conductor 36, the twelfth conductor 37, and the thirteenth conductor 38 extend along the longitudinal direction of the element body 2, the distance between the third terminal electrode 5 and the fourth terminal electrode 6 can be secured. As a result, in the electronic component 1A, a space formed between each of the seventh conductor 18, the eighth conductor 19, the tenth conductor 35, the eleventh conductor 36, the twelfth conductor 37, and the thirteenth conductor 38 and each of the third terminal electrode 5 and the fourth terminal electrode 6 can be secured. Thus, in the electronic component 1A, a region where a magnetic flux is generated can be secured, and a magnetic field can be formed around the seventh conductor 18, the eighth conductor 19, the tenth conductor 35, the eleventh conductor 36, the twelfth conductor 37, and the thirteenth conductor 38. Therefore, in the electronic component 1A, since the generation of the eddy current can be suppressed, the generation of the loss caused by the eddy current can be suppressed. As a result, a Q-value can be improved in the electronic component 1A.

Although the embodiment of the present disclosure has been described above, the present disclosure is not necessarily limited to the above-described embodiment, and various modifications can be made without departing from the gist thereof.

In the first embodiment, a mode in which the fifth conductor 16, the sixth conductor 17, the seventh conductor 18, and the eighth conductor 19 are disposed on the same straight line in the first direction D1 has been described as an example. However, the fifth conductor 16, the sixth conductor 17, the seventh conductor 18, and the eighth conductor 19 are not necessarily disposed on the same straight line.

In the second embodiment, a mode in which the tenth conductor 35 and the twelfth conductor 37 are disposed on the same straight line in the first direction D1 has been described as an example. However, the tenth conductor 35 and the twelfth conductor 37 are not necessarily disposed on the same straight line. Furthermore, in the second embodiment, a mode in which the eleventh conductor 36 and the thirteenth conductor 38 are disposed on the same straight line in the first direction D1 has been described as an example. However, the eleventh conductor 36 and the thirteenth conductor 38 are not necessarily disposed on the same straight line.

In the above embodiment, a mode in which the electronic component 1 includes the first resonator K1, the second resonator K2, the third resonator K3, and the fourth resonator K4 has been described as an example. However, it is sufficient that the electronic component includes at least three resonators.

In the above embodiment, a mode in which the ground conductor is connected to one end of the conductor and the capacitor conductor is connected to the other end of the conductor in each of the first resonator K1, the second resonator K2, the third resonator K3, and the fourth resonator K4 has been described as an example. However, the resonator may include a pair of conductors and a connection conductor connecting the pair of conductors.

In the above embodiment, a mode in which the length in the first direction D1 is longer than the length in the third direction D3, as viewed from the second direction D2, has been described as an example for all conductors disposed in the element body 2. However, a part of the conductors disposed in the element body 2 does not necessarily have a length in the first direction D1 longer than the length in the third direction D3, as viewed from the second direction D2.

What is claimed is:

1. An electronic component comprising:
an element body having a pair of end surfaces facing each other in a first direction, a pair of main surfaces facing each other in a second direction, and a pair of side surfaces facing each other in a third direction; and
a first resonator, a second resonator, and a third resonator disposed in the element body,
wherein the first resonator includes a first conductor extending in the second direction,
the first conductor extends in a direction in which the first resonator, the second resonator, and the third resonator are arranged side by side as viewed from the second direction, and
the first resonator is disposed between the second resonator and the third resonator.

2. The electronic component according to claim 1, further comprising a pair of side electrodes disposed on the pair of side surfaces, respectively, and connected to ground.

3. The electronic component according to claim 2, wherein the first conductor is disposed in a central region of the element body in the third direction as viewed from the second direction.

4. The electronic component according to claim 2, further comprising:
a ground conductor electrically connected to the pair of side electrodes; and
a capacitor conductor,
wherein one end of the first conductor is connected to the ground conductor, and
an other end of the first conductor is connected to the capacitor conductor.

5. The electronic component according to claim 1, wherein the second resonator includes a second conductor extending in the second direction,
the third resonator includes a third conductor extending in the second direction, and
at least one of the second conductor and the third conductor has a length in the first direction longer than a length in the third direction as viewed from the second direction.

6. The electronic component according to claim 5, wherein each of the first conductor, the second conductor, and the third conductor has a length in the first direction longer than a length in the third direction as viewed from the second direction.

7. The electronic component according to claim 1, wherein the first resonator includes a plurality of the first conductors.

8. The electronic component according to claim 1, further comprising a fourth resonator disposed in the element body,
wherein the fourth resonator includes a fourth conductor extending in the second direction, and
the third resonator, the first resonator, the second resonator, and the fourth resonator are disposed in order from a side of one of the pair of end surfaces to a side of an other of the pair of end surfaces in the first direction.

9. The electronic component according to claim 8, wherein the fourth conductor has a length in the first direction longer than a length in the third direction as viewed from the second direction.

10. The electronic component according to claim 8, further comprising:
a first terminal electrode disposed on the one end surface; and
a second terminal electrode disposed on the other end surface,
wherein the third resonator is electrically connected to the first terminal electrode, and
the fourth resonator is electrically connected to the second terminal electrode.

11. The electronic component according to claim 5, wherein the second resonator includes a plurality of the second conductors.

12. The electronic component according to claim 7, wherein the plurality of first conductors are arranged side by side in the third direction.

13. The electronic component according to claim 1, wherein a cross-sectional shape of the first conductor orthogonal to the second direction is a shape in which a plurality of circles overlap.

14. The electronic component according to claim 1, wherein the first conductor has a recess on a side surface, the recess extending in the second direction.

15. The electronic component according to claim 2, further comprising a plurality of conductors disposed in both end portions of the element body in the first direction and in both end portions of the element body in the third direction, the plurality of conductors extending in the second direction.

16. The electronic component according to claim 15, wherein the plurality of conductors are electrically connected to the pair of side electrodes.

17. The electronic component according to claim 2, further comprising:
a first ground conductor disposed closer to one of the pair of main surfaces; and
a second ground conductor disposed closer to an other of the pair of main surfaces,
wherein one end of the first conductor is connected to the first ground conductor,
an other end of the first conductor is connected to a capacitor conductor, and
the capacitor conductor faces the second ground conductor in the second direction.

18. The electronic component according to claim 17, further comprising:
a first capacitor conductor that is the capacitor conductor included in the first resonator;
a second capacitor conductor that is a capacitor conductor included in the second resonator; and
a conductor disposed between each of the first capacitor conductor and the second capacitor conductor, and the second ground conductor in the second direction.

19. The electronic component according to claim 5, wherein the first conductor, the second conductor, and the third conductor are disposed on a same straight line in the first direction.

20. The electronic component according to claim 10, wherein the first terminal electrode and the second terminal electrode are formed to wrap both of the pair of main surfaces from the pair of end surfaces, respectively.
